(19) United States
(12) Patent Application Publication
(10) Pub. No.: US 2006/0081983 A1
(43) Pub. Date: Apr. 20, 2006

(54) WAFER LEVEL MICROELECTRONIC PACKAGING WITH DOUBLE ISOLATION

(76) Inventors: Giles Humpston, San Jose, CA (US); Bruce M. McWilliams, San Jose, CA (US)

Correspondence Address: TESSERA;LERNER DAVID et al., 600 SOUTH AVENUE WEST, WESTFIELD, NJ, 07090, US

(21) Appl. No.: 10/711,945

(22) Filed: Oct. 14, 2004

(51) Int. Cl. H01L 23/52

(52) U.S. Cl. 257/738

(57) ABSTRACT

A microelectronic package may include front and rear covers overlying the front and rear surfaces of a microelectronic element such as an infrared sensor and spaces between the microelectronic element and the covers to provide thermal isolation. A sensing unit including a microelectronic package may include a reflector spaced from the front cover to provide an analyte space, and the microelectronic element may include an emitter and a detector so that radiation directed from the emitter will be reflected by the sensor to the detector, and such radiation will be affected by the properties of the analyte in the analyte space. Such a unit provides a compact, economical chemical sensor. Other packages include elements such as valves for passing fluids into and out of the spaces within the package itself.

### BACKGROUND OF THE INVENTION

The present invention relates to microelectronic packages and methods of making the same.

Devices such as semiconductor chips and crystals, and related devices referred to as microelectromechanical systems (“MEMS”) typically are provided in packages which protect the device from the environment, and which facilitate mounting the device in a larger assembly as, for example, mounting of the device to a circuit panel.

Packages for certain devices are formed with cavities inside the package. For example, piezoelectric elements such as quartz crystals are widely used as frequency reference elements in electronic systems. A quartz crystal can be provided with electrodes and shaped so that when the electrodes are properly energized, the crystal vibrates at a precise, predictable frequency, and generates an electrical signal having that frequency. That frequency is used as a reference in a quartz crystal oscillator. Oscillators of this type are used as frequency and timing standards in many different electronic circuits as, for example, as reference clocks in computers, and as frequency reference elements in radio communication devices such as cellular telephones. To allow the crystal to vibrate, it should be mounted inside a cavity within the package. Also, because the frequency of oscillation of such a crystal is influenced by adsorption and condensation on the crystal surfaces, the package may be sealed. Therefore, crystals typically are provided in cavity packages that are hermetically sealed against the entry of water vapor. As used in this disclosure, the term “hermetically sealed” means that the package has a helium leak rate no greater than 2×10⁻⁸ cm³/sec-Atm.

Conventional cavity packages for crystals use larger elements such as metal cans to contain the crystal along with an integrated circuit chip-bearing elements of the oscillator circuit. Other types of packages for crystal oscillators include ceramic substrates having cavities formed therein, with a lid mounted to the substrate. The crystal and a chip having a portion of the oscillator circuit are mounted on the substrate and covered by the lid. Although packages of these types provide acceptable function in many applications, further improvement would be desirable. It would be desirable to reduce the cost and size of such a package. Reduction in the size of the package would be desirable not only to reduce the overall size of the assembly incorporating the package, but also to reduce the lengths of leads and circuit traces connecting the oscillator with other elements of the circuit.

It is also desirable to provide optically sensitive microelectronic elements in packages defining cavities. For example, sensors capable of detecting light in the infrared region of the spectrum can be used in chemical analysis systems. These sensors can be influenced by temperature changes. Such a sensor can be isolated from temperature changes in the environment by packaging it inside a cavity defined by a conventional package, and equipping the package with a window transparent to the infrared radiation to be detected. However, this approach adds cost and bulk to the assembly. Moreover, a chemical analysis system typically includes a sensor and a separately packaged infrared transmitter such as a light-emitting diode or laser. The transmitter and the detector are mounted at separate locations on a supporting structure with a space between them for passage of the substance to be analyzed (referred to herein as the “analyte”). The requirements to handle, ship, store and mount two separate devices further add to the cost of the overall system. Moreover, these devices typically must be mounted in precise alignment with one another so that infrared light emitted by the emitter will impinge on the detector. The need for such precise alignment further adds to the cost of the system.

In still other applications, it is desirable to provide a package for a microelectronic device with a valve. For example, a package may be provided with a check valve which allows removal of air from the package during manufacture, but which then closes to temporarily isolate the package from the outside environment until the valve opening can be permanently sealed. In still other applications, a package may be designed to admit fluid during operation. For example, a biochemical sensor may be mounted in a package, so that an analyte can be directed into the package itself to physically contact the device. It would be desirable to provide valve which can be used to control such fluid flow. One form of valve which can be used as a check valve or as a fluid control valve includes a movable element, typically a small sphere, and a conical seat. It is difficult to form a conical seat in a silicon element, because the normal etching processes for silicon tend to follow the crystal planes of the silicon and thus produce tetrahedral etched features rather than conical features.

### BRIEF SUMMARY OF THE INVENTION

One aspect of the present invention provides a microelectronic package including a microelectronic element having front and rear sides. A front cover overlies the front side of the microelectronic element, the front cover being spaced from the front side so as to define a front space between the front side and the front cover. A rear cover overlies the rear side of the microelectronic element and is spaced from the rear side so as to define a rear space between the rear side of the microelectronic element and the rear cover. The package according to this aspect of the invention desirably further includes one or more seals surrounding at least a portion of the microelectronic element. These seals connect the covers to the microelectronic element, to one another or both. The package desirably includes electrically conductive connections extending from a portion of the microelectronic element surrounded by the seals through at least one of these covers. The front and rear covers, and the front and rear spaces, desirably isolate the microelectronic element from thermal transients and also provide mechanical protection to at least a part of the microelectronic element.

In one arrangement, the microelectronic element includes a central portion and a peripheral portion surrounding the central portion. The seals include a front seal extending between the peripheral portion of the microelectronic element and the front cover, and a rear seal extending between the peripheral portion of the microelectronic element and the rear cover. The microelectronic element and the covers may have substantially equal dimensions in horizontal directions parallel to the front surface of the microelectronic element.

In another arrangement, the seals include a loop seal extending between the front and rear covers, so that the loop seal and the front and rear covers cooperatively define a sealed chamber encompassing the front and rear spaces, the microelectronic element being disposed within this chamber. In certain embodiments, the microelectronic element does not contact the loop seal, so that the microelectronic element is effectively suspended inside of the chamber as, for example, by spacers supporting the element out of contact with the front and rear covers. This arrangement provides excellent thermal isolation of the microelectronic element.

A further aspect of the invention provides a sensor which includes a microelectronic element, again having front and rear surfaces. The microelectronic element includes an emitter adapted to emit radiation in a selected wavelength band forwardly from the front surface, and also includes a detector adapted to detect radiation in this wavelength band which is directed rearwardly to the front surface. The emitter and detector may include semiconductor elements formed integrally with the microelectronic element as, for example, where the microelectronic element includes a unitary substrate and the emitter and detector are semiconductor elements epitaxially grown on the substrate. The sensor according to this aspect of the invention desirably also includes a front over overlying the front surface of the microelectronic element. The front cover has a window portion aligned with the emitter and detector, such window portion desirably being substantially transparent to radiation in the aforementioned wavelength band. The sensor may further include a seal encircling the emitter and detector and extending rearwardly from the front cover, and also may also include one or more electrical connectors extending through the front cover, the electrical covers being electrically connected to the microelectronic element. The seal may extend to the microelectronic element in the manner of the front seal discussed above. Where the sensor includes a rear cover overlying the rear surface of the microelectronic element, the seal may extend to the rear cover. In either case, the seal desirably provides environmental protection to the emitter and detector. At least the window portion of the front cover may be spaced from the microelectronic element, so that the front cover and microelectronic element define a front space therebetween.

The sensor desirably further includes a reflector overlying the front cover, the reflector being operative to reflect energy emitted by the emitter through the front cover, back through the front cover to the detector. The reflector may be spaced from the front cover so that the reflector and the front cover cooperatively define an analyte space. In this arrangement, the light emitted by the detector passes through the front cover and through the analyte space to the reflector, and also passes through the analyte space and front cover on route back to the detector. Thus, the amount of light reaching the detector will be affected by absorption, scattering or other interaction between the light and the analyte in the analyte space. The sensor, thus, provides a self-contained unit capable of detecting changes in the analyte. For example, the analyte space may be exposed to the environment so that the analyte in the space is environmental air. The sensor may be used to detect contaminants such as carbon monoxide or smoke in the air. The sensor provides an extraordinarily compact, self-contained device. The microelectronic element desirably includes some or all of the circuits needed to drive the emitter and process signals from the detector.

In a variant of this approach, the reflector itself may be sensitive to an analyte. In this arrangement, the reflector can be spaced from the front cover or can directly overlie the front cover. The reflector may have electrically conductive features for connecting the unit to a larger circuit, and these electrically conductive features desirably are electrically connected to the electrical connections extending through the front cover. The conductive features on the reflector may include features such as bond pads exposed at a surface of the reflector facing away from the microelectronic element and front cover, so that the entire unit can be mounted on a circuit board or other support. In a further variant, the reflector may be integrated with the circuit board or other support. In this arrangement, the unit without the reflector is united with the reflector when the unit is mounted to the circuit board.

A related aspect of the invention provides methods of making packages. Methods according to this aspect of the invention desirably include the steps of assembling a front cover plate to a front side of a main wafer, so that the front cover plate is spaced from the front side of the main wafer, and providing front spacing elements extending between the front cover plate and the main wafer. The method desirably further includes assembling a rear cover plate to a rear side of the main wafer so that the rear cover plate is spaced from the rear side of the main wafer, and providing rear spacing elements extending between the rear side of the main wafer and the rear cover plate. After the assembling and providing steps, the plates and wafer desirably are severed to form a plurality of units, each including a region of the main wafer, regions of the front and rear plates, and front and rear spacing elements connecting the front and rear plate regions to the region of the main wafer. The step of providing spacing elements may include the steps of providing front and rear seals, and the severing step may be conducted so as to sever the plates and the wafer along the seals. A method according to this aspect of the invention may further include the step of providing a reflector plate overlying the front plate and reflector spacing elements extending between the reflector plate and the front plate prior to the severing step, so that each unit formed in the severing step will also include a portion of the reflector plate.

These and other objects, features and advantages of the present invention will be more readily apparent from the detailed description of the preferred embodiments set forth below, taken in conjunction with the accompanying drawings.

### BRIEF DESCRIPTION OF THE DRAWINGS

FIG. 1 is a sectional view of components during one stage of a process according to one embodiment of the invention.

FIG. 2 is a fragmentary plan view of a component shown in FIG. 1 on a reduced scale relative to FIG. 1.

FIG. 3 is a view similar to FIG. 1, showing to components of FIG. 1 at a later stage of the process.

FIG. 4 is a fragmentary sectional view taken along line 4-4 in FIG. 1.

FIG. 5 is a sectional view depicting a unit made in accordance with FIGS. 1-4, in conjunction with a circuit board.

FIG. 6 is a view similar to FIG. 5 but depicting a unit according to a further embodiment of the invention.

FIG. 7 is a further sectional view depicting a unit in accordance with another embodiment of the invention.

FIG. 8 is a sectional view depicting a unit according to a still further embodiment of the invention in conjunction with a circuit board.

FIG. 9 is a view similar to FIG. 8 but depicting a unit according to yet another embodiment of the invention.

FIGS. 10, 11, 12 and 13 are sectional views depicting a unit according to a still further embodiment of the invention.

### DETAILED DESCRIPTION OF THE INVENTION

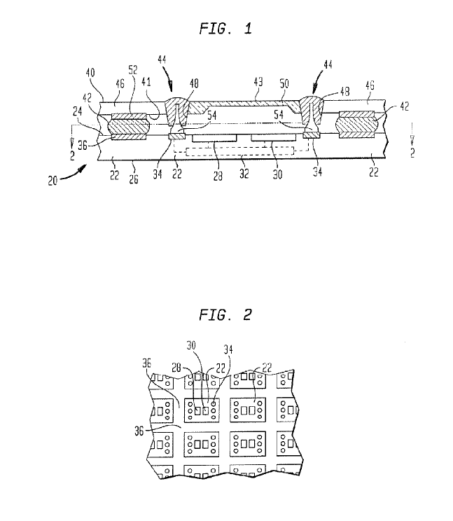

A fabrication process according to one embodiment of the present invention utilizes a wafer 20, referred to herein as the “main wafer.” Wafer 20 includes a plurality of individual regions 22 formed as an integral unit. Wafer 20 typically is formed as a unitary body of semiconductor material such as silicon or a compound semiconductor as, for example, silicon carbide or a III-V compound semiconductor such as gallium arsenide, indium gallium arsenide or the like. The wafer may include plural semiconductors as, for example, features formed from one or more compound semiconductors on an underlying layer of silicon or silicon carbide material, together with additional material such as insulators and metallic conductors. The wafer has a front surface 24 and a rear surface 26. Each region 22 includes an emitter 28 adapted to emit radiant energy in a preselected wavelength band. For example, the emitter may incorporate one or more light-emitting diodes or lasers. The emitter is adapted to direct radiant energy in a forward direction (toward the top of the drawings in FIG. 1) from the front surface 24 of the wafer. Each region 22 of the wafer also includes a detector 30 as, for example, one or more photodiodes or phototransistors, adapted to detect light in the preselected wavelength band used by transmitter 28 impinging on the front surface of the wafer. Each region 22 of the wafer also desirably includes internal electronic components 32 connected to emitter 28, detector 30 or both. The internal electronic components may include, for example, a driver circuit for actuating the emitter and an amplifier for amplifying signals from detector 30.

Additional circuits also may be incorporated within internal electronic components 32. Components 32 also may include passive devices such as capacitors, inductors and resistors used in association with the emitter, the detector or both. Each region further includes terminals 34 exposed at the front surface 24 of the wafer, at least some of these terminals being electrically connected to the internal electronic components 32, to the emitter 28 or to the detector 30. As used in this disclosure, a conductive feature such as a contact 34 is said to be “exposed at” a surface of a larger body if the conductive feature can be contacted by a theoretical point moving in the direction towards the larger body, normal to the surface of the larger body. Thus, contacts 34 may project from the front surface 24 of the wafer, may be flush with such surface, or may be recessed below such surface.

Wafer 20 also has seal lands 36 exposed at front surface 24. The seal lands, seen in cross-section in FIG. 1, are in the form of a grid defining the borders between adjacent regions 22. The front surface of each region is completely encircled by the seal lands. Stated another way, the seal lands form a rectangular frame around the front surface of each region 22, as best seen in plan view in FIG. 2. The main wafer has a corresponding pattern of rear seal lands 38 (FIG. 1) on the rear surface 26, rear seal lands 38 are aligned with seal lands 36 at the borders of the various regions 22.

In the assembly method, a front cover plate 40 having an interior surface 41 and an exterior surface 43 is assembled to the front side of wafer 20 so that the interior surface 41 faces toward the wafer. The front cover plate 40 is supported above front surface 24 by front spacer elements 42, and electrical connections 44 are formed so as to extend from contacts 34 at the front surface of the wafer, through the front cover plate. Processes for attaching cover plates to wafers are further disclosed in certain embodiments of co-pending, commonly assigned U.S. Provisional Patent Application Nos. 60/506,500, filed Sep. 26, 2003; 60/515,615, filed Oct. 29, 2003; 60/532,341, filed Dec. 23, 2003; and 60/568,041, filed May 4, 2004, the disclosures of which are hereby incorporated by reference herein. The processes taught in these applications may be used to attach the cover plate.

In the particular embodiment depicted in FIG. 1, cover plate 40 includes a plurality of regions 46 corresponding to the regions 22 of the wafer. The interior surfaces of holes 48 desirably are covered by a thin coating of a solder-wettable metal. Each region includes holes 48 at locations corresponding to the locations of contacts 34 on the corresponding regions 22 of the wafer. Each region of the cover plate also has a window region 50 at a location corresponding to the locations of the emitter 28 and detector 30 in the associated regions 22 of the wafer. At least the window regions 50 of the cover plate are substantially transparent to the radiation in the aforesaid wavelength band. For example, where the emitter is adapted to emit infrared radiation, the window regions 50, and desirably the entire cover plate 40, may be formed from silicon, sapphire, germanium or other suitable material transparent to infrared radiation. Silicon is preferred, because it can be readily processed, and well-known coating processes are available for coating the silicon, at least in the window regions, to minimize reflectivity and thus improve transparency at infrared wavelengths. Moreover, where the main wafer 20, is formed principally from silicon, a silicon cover plate will have the same coefficient of thermal expansion (“CTE”) as the main wafer. Matching the CTE of the cover plate with the CTE of the main wafer facilitates registration of the features on the cover plate with the features on the main wafer during processing and handling, and also reduces thermally-induced stresses in the finished assembly.

In the embodiment illustrated, front spacer elements 42 are formed as seals extending entirely around the front surface of each region. Cover plate 40 has seal lands 52 on an inner surface 41. The seal lands 52 are metallic, solder-wettable structures arranged in a pattern corresponding to the pattern of seal lands 36 on the front surface 24 of the wafer. Thus, seal lands 52 extend along the borders between the various regions 46 of the cover plate, so that the seal lands 52 surround each region of the cover plate.

As described in greater detail in certain of the aforementioned patent applications, the process of forming electrical connections 44 includes providing studs 54 projecting forwardly from contacts 34. Such studs may be formed, for example, by use of a wire-bonder. The cover plate 40 is placed onto the main wafer 20 and supported above the main wafer as, for example, by suitable temporary spacers (not shown) disposed between the main wafer and the cover plate. A bonding material, such as a solder, is introduced into holes 48 as, for example, by placing solder balls on the exterior surface 43 of the cover plate, in alignment with the holes. At the same time, solder is applied to the holes (not shown) which extend through the cover plate at or near the seal lands 52 at spaced-apart locations along the seal lands. The solder is then reflowed as by heating the assembly. The molten solder wets the interior surfaces of the holes and also wets the studs 54. The solder introduced to the holes 48 wets the interior surfaces of the holes and also wets the studs 54, so that the solder seals the holes and also forms electrical connections 44, exposed at the exterior surface 43 of the cover plate and electrically connected to the terminals 34. The solder introduced through or near the seal lands 52 wets the seal lands 52 on the cover plate and also wets the front seal lands 36 on the main wafer, thereby forming continuous seals 42, extending around the perimeter of each region 22 of the main wafer. Other conductive materials such as organic conductive materials can be used instead of solder

Because the electrical connections from each region 22 of the wafer extend through the front cover plate 40 within the area encompassed by the seal 42, there is no need for the electrical connections to cross the seal. As explained in greater detail in the aforementioned co-pending applications, this simplifies the construction of an effective seal. The steps used to form the electrical connections 44 and seals 42 can be varied. For example, as disclosed in the aforementioned co-pending applications, electrical connections 44 can be fabricated without the use of studs 54, provided that the solder or other conductive bonding material introduced at holes 48 wets the contacts 34 of the main wafer. Also, seals 42 need not be formed from solder; other materials and techniques may be used. For example, seals 42 may be formed from materials such as organic or inorganic adhesives instead of solders. Also, the seals may be formed by applying the material of the seal to the cover plate, to the main wafer or both, in a pattern corresponding to the pattern of seal lands discussed above, before assembling the cover plate and main wafer with one another.

The seals may be formed by an intermediate silicon wafer, which is etched to leave only a grid of silicon strips in a layout similar to the layout of seal lands 36 discussed above with reference to FIG. 2. That intermediate wafer is placed between the cover plate and main wafer during assembly of the cover plate and main wafer, and then anodically bonded to the cover plate and main wafer so as to form the seals. In such an arrangement, the cover plate and the main wafer need not have the seal lands discussed above.

With the front cover plate assembled to the wafer 20, there is a front space 58 between each region 22 of the main wafer and the corresponding region 46 of the front cover plate, and that space is entirely surrounded by the seals 42.

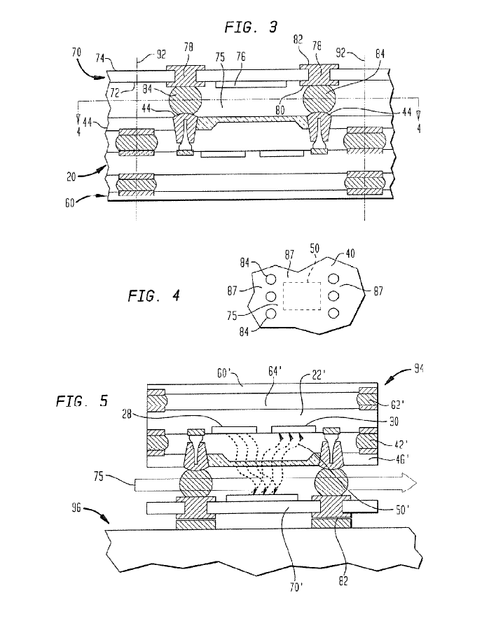

The assembly process further includes attaching a rear cover plate 60 (FIG. 3) to the rear side of the main wafer and providing rear support elements 62 between the rear surface 26 of the main wafer and the rear cover plate, so that there is a rear space 64 between each region 22 of the main wafer and the rear cover plate. Most preferably, the rear spacers 62 are seals formed in a pattern similar to the pattern of seals 42 between the main wafer and front cover plate, so that seals 62 surround the rear surface of each region 22 and surround each rear space 64. Rear seals 62 are disposed in alignment with front seals 42. The rear spacer elements or seals 62 can be formed in the same ways as discussed above with reference to the front spacer elements or seals 42. The rear cover plate 60 may be attached to the main wafer 20 before, after or simultaneously with the front cover plate 42. Most typically, however, the front cover plate is assembled to the main wafer before application of the rear cover plate, so that the sensitive structures exposed at the front surface of the main wafer are protected preferably in the process.

The assembly process further includes the step of attaching a reflector plate 70 to the other elements of the assembly, so that the reflector plate is disposed forward of the front plate 40. Reflector plate 70 has a proximal surface 72 and a distal surface 74. The reflector plate 70 in this embodiment is formed principally from a dielectric material as, for example, glass, ceramic or a polymeric dielectric material. The reflector plate 70 has reflector regions 76 on its proximal surface. The reflector regions are reflective to radiant energy in the wavelength band used by the emitter and detector. Merely by way of example, the reflector plate 70 may include a metallic or other highly reflective coating on the proximal surface in the reflector regions 76. Reflector regions 76 are positioned in alignment with window regions 50. Reflector plate 70 further includes electrically conductive elements 78 extending through the reflector plate so as to define bond pads 80 exposed at the proximal surface 72 of the reflector plate, and terminals 82 exposed at the distal surface 74 of the reflector plate. The bond pads 80 are disposed in a pattern corresponding to the pattern of the conductive elements 44 which extend through the front cover plate.

Reflector spacing elements 84 are provided between the conductive elements 44, exposed at the cover plate 40, and the bond pads 80 of the reflector plate 70. Reflector spacing elements 84 desirably are formed from a conductive material as, for example, from solder balls or solid-core solder balls incorporating a thin coating of a solder or other conductive bonding material overlying a solid central core, such as a sphere of copper or other conductive metal, or a non-metallic sphere having a coating of a metal on its surface. The reflector spacing elements 84 electrically connect the conductive elements 78 of the reflector plate to the electrical connectors 44 of the cover plate, and hence, to the contacts 34 of wafer 20.

Reflector spacing elements 84 cooperatively support reflector plate 70 above or forward of front cover plate 40. Thus, the reflector plate 70 and front plate 40 cooperatively define an analyte space 75 overlying the front cover plate 40 in alignment with each window region 50. The reflector spacing elements 84, however, do not form seals around the analyte spaces 75. That is, as best seen in plan view in FIG. 4, there are gaps 87 between the reflector spacing elements.

In a variant, reflector spacing elements 84 may be formed integrally with electrical connectors 44 as, for example, by extending the studs 54 forwardly beyond the upper surface 46 of cover plate 40. Alternatively, the reflector spacing elements 84 may be formed integrally with the conductive elements 78 of the reflector plate 70. Also, although the conductive elements 78 are depicted in FIG. 3 as simple, straight through-vias, the conductive elements may include elements such as traces extending along a surface of reflector plate 70, or within the reflector plate 70, so as to provide terminals 82 at locations offset from the contact pads 80, and hence, offset from the contacts 34 of the wafer in horizontal directions, parallel to the planes of the wafer and plates.

After attachment of the reflector plate 70, the assembly is severed along severance planes 92 (FIG. 3) as, for example, by sawing or cutting through all of the plates and the wafer, using a conventional wafer saw or other severing methodology, such as etching, laser ablation or the like. Severance planes 92 extend through the front seals 42 and rear seals 62, so that each such seal is subdivided during the severing step. The severing step forms individual units 94, depicted in FIG. 5 in a position inverted relative to FIG. 3. Each such unit 94 includes a region 22′ of the main wafer constituting an individual semiconductor chip, together with a region 46′ of the cover plate constituting a cover overlying the front surface of the wafer (shown facing downwardly in FIG. 5) with a front space 50′ between the front surface of the chip and the front cover 46′. Each unit 94 also includes a rear cover 60′ formed from a portion of rear cover plate 60 and a rear space 64 between the chip 22′ and the rear cover 60′. The front and rear spaces in the finished unit remain sealed by the front seals 42′ and rear seals 62′, left in place after the severing operation. Each unit 94 also includes a reflector 70′ having a reflective region 76′ aligned with the window region 50′ of the front cover, and hence, aligned with the emitter 28 and detector 30 of the chip. The analyte space 75 between the front cover 46′ and reflector 70′ is open to the outside of the unit through the gaps between reflector support elements 84. The unit can be mounted on a circuit board 96, or other suitable support, and electrically connected to a larger circuit by attaching the terminals 82 exposed on the distal side of reflector 70′ as, for example, using surface-mounting techniques to solder the terminals 82 to the contact pads of the circuit panel. The unit can be mounted in other ways as, for example, mounting the unit face-up with terminals 82 facing away from the circuit panel and wire-bonding the terminals to the circuit panel.

Each unit forms a self-contained analytical system. A gas or other fluid to be monitored can pass through the analyte space 75 between the reflector 70′ and front cover 46′. As the analyte passes through the analyte space, radiant energy is emitted by emitter 28, passes through window region 50, and through the analyte space 75 and the analyte in such space to reflector 70′. The radiant energy reaching the reflector is reflected back to the detector 30, again passing through the analyte space 75. Thus, if the analyte in the space contains a constituent which absorbs or otherwise attenuates the radiant energy, the radiant energy reaching detector 30 will be reduced. The internal circuit 32 provides a signal indicative of the amount of radiant energy reaching detector 30, or more preferably, a signal reflecting the relationship between the energy emitted by emitter 28 and the amount of radiant energy detected by detector 30. Because the emitter and detector are closely coupled to the internal circuitry, with only very short connecting traces inside chip 22′, possibilities for electrical interference influencing the signals reaching the internal circuitry from the detector are minimized. Further, chip 22′ is thermally isolated from the environment by front and rear spaces 50′ and 64′. The active elements of the chip 22′ are also well protected from damage due to environmental contamination.

Optionally, spaces 50′ and 64′ may be evacuated or filled with an inert fluid such as an inert gas during the assembly process, so as to increase the thermal isolation of chip 22′. Seals 62′ and 42′ desirably are hermetic seals. To further protect the active elements of the chip from environmental damage, a substance which absorbs, adsorbs or reacts with oxygen or other expected contaminants in the environment, may be provided within the front space, rear space or both. Such a substance is commonly referred to as a “getter.” The entire unit is extraordinarily compact. It has dimensions in the horizontal directions, parallel to the front and rear surfaces of chip 22, substantially equal to the horizontal dimensions of chip 22′. Moreover, the entire unit can be fabricated economically.

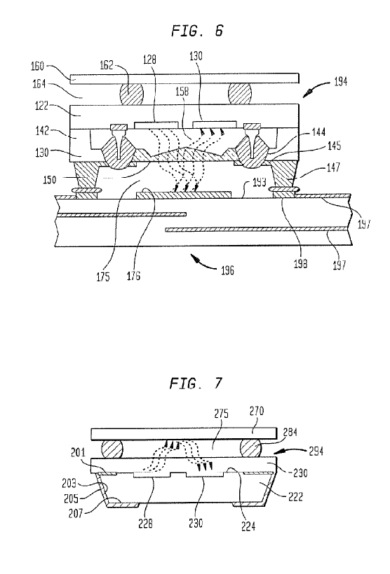

A unit in accordance with a further embodiment of the invention (FIG. 6) includes a chip 122 with an emitter 128 and detector 130 similar to those discussed above. Here again, the unit includes a front cover 130 overlying the front surface of the chip, with a window region 150 aligned with the emitter and detector. In this embodiment as well, there is a front space 158 disposed between the front face of the chip and the front cover, and spacers in the form of seals 142 extend between the front face of the chip and the front cover. Here again, the seals 142 extend around the perimeter of the front space so as to seal the front space 158 from the exterior environment. In this embodiment, seals 142 are formed integrally with front cover 130 and are bonded to the front face of chip 122 by a process such as anodic bonding or adhesive bonding. Units according to this embodiment of the invention are made by a process generally similar to that discussed above with reference to FIGS. 1-5. Thus, front cover 130 is provided in the form of a cover plate which, in this case, has the seals 142 formed thereon, so that the seals are attached to a wafer incorporating numerous chips 122 prior to severing the wafer and cover plate. In this embodiment as well, electrical connections 144 extend through the front space 150 and through front cover plate 130 inside the space encompassed by seal members 142. In this embodiment, the electrical connections include traces 145 extending in lateral or horizontal directions parallel to the front face of the chip, and also include electrically conductive projections 147 extending forwardly from the exterior face of front cover 130. Projections 147 and traces 145 desirably are provided on the cover plate before the cover plate is assembled to the wafer during the fabrication process. Merely by way of example, projections 147 may be of the types disclosed in co-pending, commonly assigned U.S. Provisional Patent Application Nos. 60/533,210; 60/533,393; and 60/533,437, the disclosures of which are hereby incorporated by reference herein. The projections and traces may be provided directly on the cover plate or on a separate substrate (not shown) attached to the cover plate, desirably prior to assembly of the cover plate with the wafer.

The unit 194 further includes a rear cover plate 160 mounted to the rear surface of chip 122, so that the rear cover plate and the chip cooperatively define a rear space 164. In this embodiment, however, the rear cover plate is not sealed to the chip, but instead is supported by rear spacer elements 162 and support columns which may be formed from any suitable material. The rear cover plate 160 and rear space 164 still provide some thermal and mechanical isolation of the rear face of the chip. In a further variant, rear space 164 may be filled, before or after severing the wafer and cover plates, with a solid or semi-solid thermal insulation material. In yet another variant, the rear cover plate and rear support elements may be omitted entirely.

The unit 194 of FIG. 6 does not include a reflector plate as a part of the unit itself. In use, the unit 194 is assembled with a circuit board 196 having contact pads 198 disposed thereon, and having electrically conductive traces 197 on a surface of the circuit board or within the circuit board connected to the contact pads and extending to other elements (not shown) of a larger circuit. Circuit board 196 has horizontal dimensions larger than the horizontal dimensions of unit 194. Projections 147 are secured to contact pads 198 of the circuit board as, for example, by surface-mounting or other bonding techniques, or by mechanically engaging the projections with the conductive features of the circuit board. The projections 147 support the unit above the exposed face 193 of the circuit board. The circuit board itself is provided with a reflective element 176 adapted to reflect the radiant energy in the preselected wavelength band used by emitter 128 and detector 130. For example, reflective element 176 may be formed from metallic materials such as copper and gold used to form the terminals 198 and other conductive features of circuit board 196. Such a reflective surface may be formed at little or no additional cost during fabrication of the circuit board. Thus, when the unit is mounted on the circuit board, the unit and the circuit board cooperatively define an analyte space 175 between the front cover 130 and the confronting face 193 of the circuit board. In this embodiment, the analyte flows through the analyte space. Once again, radiant energy passing from the emitter 128 to detector 130 by way of reflector 176 is absorbed or otherwise affected by the analyte, so that the internal circuitry (not shown) within chip 122 can provide a signal representing the effect of the analyte on the transmitted radiant energy, and hence, representing a property of the analyte.

Window region 150 of the front window is shaped to act as a pair of prisms or, in effect, a lens, to direct the light from emitter 128 onto reflector 176 and to direct the light from reflector 176 onto detector 130. Other types of optical elements, such as spheric or aspheric lenses, holograms, mirrors and the like may be formed integrally with the cover plate 130, or provided on the cover plate by attaching separately formed optical elements thereto. Also, the cover plate may include wavelength-selective optical elements as, for example, a filter adapted to transmit wavelengths within the band of wavelengths used by the emitter and detector, but to block other wavelengths. Such a filter can be used to reduce the effect of ambient light on the detector.

In the embodiments discussed above, the reflector serves only to change the direction of the radiant energy. In a variant of these embodiments, the reflector may be formed form a material which is reactive with a constituent in the analyte, so that the reflectivity of the reflector varies with the composition of the analyte. For example, a metallic reflector may be oxidized or tarnished by constituents in room air, so that the reflectivity of the reflector in the preselected wavelength band decreases with time. The signal produced by the detector can be used to monitor the rate of such decrease and thereby give an indication of the rate of decrease in reflectivity, which in turn, constitutes a measure of the concentration of the constituents in the analyte which react with the reflector.

In a variant of the embodiment shown in FIGS. 1-5, the reflector 70 may be electrically connected to the chip by flexible or otherwise deformable connections, so that the terminals 82 defined by the chip carrier are movable with respect to the chip so as to compensate for differential thermal expansion of the circuit board and the elements of unit 94. The disclosures of U.S. Pat. Nos. 5,679,977 and 5,518,964 are hereby incorporated by reference herein.

An integrated unit incorporating an emitter, detector and reflector can be made using wafer scale processes and structures different from those discussed above. For example, individual optically active semiconductor elements such as emitters and detectors have been made using transparent cover layers mounted directly to the face of a chip. A unit 294 according to a further embodiment of the invention (FIG. 7) incorporates a chip 222 having an emitter 228 and detector 230 arranged to direct radiant energy forwardly from the front surface 224 of a chip. As initially fabricated in wafer form, the chip has leads 201 extending along the front surface of the chip to the boundaries between adjacent chips. In a wafer level process as described, for example, in U.S. Pat. No. 6,646,289, the wafer is united with a cover plate so that the cover plate overlies the front surface of the wafer. The wafer is etched from its rear surface to provide sloping surfaces 203, and additional leads 205 are deposited on the sloping surfaces so as to connect the leads and the contacts of the chip to terminals 207 on the rear surface of each chip. This process also requires deposition of conductive material on the inner surface of the cover plate to connect the front surface leads 201 with the leads 205 on the sloping surfaces.

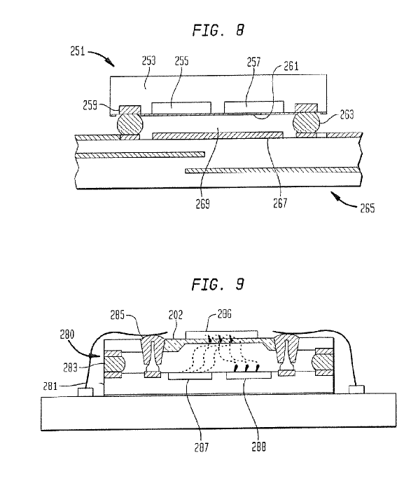

In a process according to the embodiment of FIG. 7, a reflector plate is mounted over the outer surface of the cover plate and supported from the outer surface by supporting elements. Desirably, the reflector plate is mounted over the cover plate prior to severance of the individual units from the wafer. Thus, the completed unit 294 includes a reflector 270 supported forwardly of the cover 230 by supporting elements 284 so as to provide an analyte space 275 between the cover and the reflector. Here again, the completed unit provides a fully integrated, chip-size analysis apparatus. The embodiment of FIG. 7 is less preferred, inasmuch as a complex series of operations is required to form the lead structure. Similarly, units incorporating connections and covers as shown in FIG. 7 can be provided with connections projecting forwardly beyond the exterior surface of the cover, so that the unit can be mounted in a front-down orientation on a circuit board bearing a reflector, in a manner similar to the mounting of unit 194 shown in FIG. 7. In further variants, other units can incorporate chips bearing both light-emitting elements and detectors, with or without a separate cover. For example, a unit 261 (FIG. 8) according to a further embodiment of the invention consists solely of a chip 253 having an emitter 255 and detector 267 on its front surface, and having contacts 259 exposed at the front surface. The chip optionally has a passivation layer 261 transparent to the wavelengths used by the emitter and detector covering the front surface and contacts 259 being exposed through apertures in the passivation layer. The chip is assembled to a circuit board 265 using solder masses 263 or other conductive elements which may be provided on the unit or on the circuit board during assembly. The conductive elements support the unit above the circuit board, so as to provide an analyte space 269 between the unit and the reflector 269 on the circuit board.

A unit 280 in accordance with a further embodiment of the invention (FIG. 9) includes a chip 281 front cover 282, seals 283 and connections 285 extending through the front cover similar to those used in the embodiment of FIGS. 1-5. In this embodiment, however, the front cover plate itself bears a reflective element 286. The reflective element reflects radiant energy emitted by the emitter 287 at the forward surface of the cover 282, so that the reflected light passes back to the detector 288. In this embodiment, the reflective element 286 desirably is arranged to vary its reflectivity in the wavelength band used by the emitter and detector in response to a condition prevailing outside of the unit. For example, the reflective element may be a layer or coating incorporating a chemically-sensitive reagent, so that reflectivity of the element 286 changes in response to one or more chemical species in the environment outside of the unit. The unit can be mounted as desired, so long as reflective element 286 is exposed to the environment to be monitored by the unit. For example, the unit can be mounted front-surface up on a circuit board 289, and connected by wire bonds or other suitable connections to the conductive elements of the circuit.

A cover plate bearing a sensitive reflective element of the type shown in FIG. 9 can also be incorporated in the embodiments shown in FIGS. 1-8. In this case, the element used as a reflector in the embodiments discussed above (such as reflector 70′ in FIG. 5 or reflector 270 in FIG. 7, or the reflective elements 176 and 267 of the circuit board in FIGS. 6 and 8) need not be reflective. However, the element shown as a reflector in these embodiments can be opaque so as to provide additional protection against ambient light and additional thermal and mechanical protection. Also, a unit incorporating a front cover having a sensitive reflective element may include a rear cover as shown, for example, in FIG. 5 so as to provide additional thermal and mechanical protection for the rear surface of the chip.

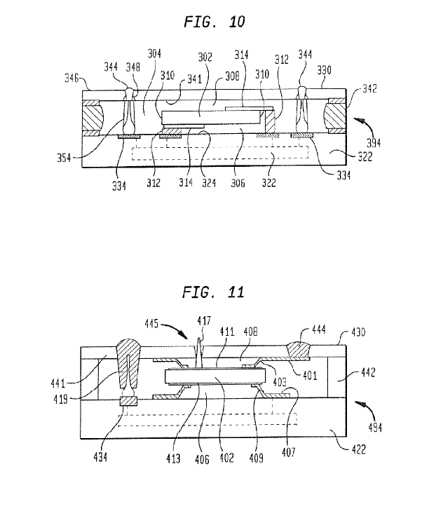

A unit 394 according to a further embodiment of the invention (FIG. 10) includes a semiconductor chip 322 and front cover 330 joined to one another and spaced apart from one another by seals 342 extending around the perimeter of the unit. A further microelectronic element 302, in this case a quartz crystal, is mounted within the space 304 between the front cover 302 and chip 322. The microelectronic element 302 is supported within space 304 so that it is spaced forwardly from the front surface 324 of the chip and rearwardly from the inner surface 341 of the front cover. Thus, there is a rear space 306 between microelectronic element 302 and the chip 322, and a front space 308 between the microelectronic element and the front cover 330. In this embodiment, chip 322 acts as a rear cover so as to define the rear space 306 behind the microelectronic element 302. Moreover, the microelectronic element is entirely encompassed within the larger sealed space 304, so that the edges 310 of the microelectronic element are spaced inwardly from seals 342. This arrangement affords excellent thermal isolation of the microelectronic element, so that it is substantially unaffected by short thermal transients. The crystal or microelectronic element 302 desirably is suspended inside space 304 by posts or other spacing elements 312 extending from the chip 322, cover element 330 or both. In the particular embodiment shown, the crystal has electrodes 314 which are connected to the posts in an arrangement which leaves the crystal free to vibrate at its resonant frequency.

Chip 322 incorporates internal circuitry 332 as, for example, a circuit for applying a driving signal to crystal 312 and detecting the frequency of oscillation of the crystal. Internal circuitry 322 may incorporate additional elements such as one or more circuits for deriving a suitable clock signal for a digital circuit from the signal generated by the crystal, subdividing or otherwise processing the clock signal to derive secondary clock signals and the like. Here again, the chip 322 includes contacts 334, and these contacts are provided with electrical connections 344 extending forwardly through space 304 and extending through front cover 330 within the region of the front cover encircled by seal 342. As in the embodiments discussed above, electrical connections 344 are sealed to the front cover. In this embodiment, connections 344 are formed by portions of studs 354 projecting forwardly through holes 348 in the front cover and sealed to the walls of such holes. The seals between posts 354 and the walls of the holes 344 may be formed by applying a flowable sealant such as a solder or other conductive or non-conductive bonding material which wets the surfaces of the posts and the interior surfaces of the holes. Alternatively or additionally, the seals may be formed by deforming the posts into engagement with the walls of the holes. This approach works best with posts formed from a malleable material with minimal resilience or spring-back as, for example, substantially pure gold. Further, seals between the projecting posts and the walls of the holes may be formed by eutectic bonding or anodic bonding between the posts and the material of the cover. For example, the walls of the holes may be coated with a small amount of tin, silicon, germanium or other material which forms a relatively low-melting alloy with gold, and the posts may be formed entirely from gold or have a gold coating on their surfaces. When the posts are engaged with the walls of the holes and the assembly is heated, diffusion between the material of the posts and the material on the walls forms an alloy having a melting point lower than the melting points of the individual elements at the interfaces between the posts and walls. With the assembly held at elevated temperature, further diffusion causes the alloying element to diffuse away from the interface, into the bulk of the gold of the posts, thereby raising the melting temperature of the material at the interface and causing the interface to freeze, forming a solid connection between the parts. In a variant of this process, where the cover plate is formed from silicon, eutectic bonding may be formed without a separate alloying element on the walls of the holes; the silicon present in the cover plate acts as the alloying element. A similar eutectic bonding process can be performed using other materials.

The assembly process used to make the unit of FIG. 8 may be similar to the assembly processes discussed above, in that a cover plate is applied and sealed to a wafer, followed by severance of the wafer and plate to subdivide these into the individual units. However, in the assembly process for the unit of FIG. 8, microelectronic elements 302 are placed onto the wafer or onto the cover plate before or during assembly of the cover plate. For example, microelectronic elements 302 may be placed onto each region of the wafer and bonded to posts 302 prior to assembly of the cover plate. Alternatively, the microelectronic element can be initially attached to the cover plate by a temporary connection formed from a vaporizable material, so that the microelectronic elements are assembled to the features of the wafer as, for example, to the posts 312 during placement of the cover plate. After placement of the cover plate, but before the spaces between the wafer and cover plate are fully sealed, the assemblage is treated to remove the temporary connections. For example, where the temporary connections are formed from a material soluble in water or, more preferably, a volatile solvent such as an organic material or a halogenated hydrocarbon, the space between the cover plate and wafer can be flushed with a solvent to remove the temporary connections and then flushed with a gas, baked at elevated temperatures or both to remove solvent residues.

The finished unit can be handled and mounted in substantially the same manner as a semiconductor chip. It can be connected to external circuitry through the connections 344 which define terminals exposed at the exterior surface 346 of the front cover. The unit provides an extraordinarily compact, self-contained quartz crystal oscillator. Because the crystal is mounted in close proximity to the internal circuitry 332 of the chip and connected to such internal circuitry by very short connections, the unit has low susceptibility to electromagnetic interference. Moreover, the unit is well adapted to operation at high frequencies. The unit of FIG. 10 can be mounted directly to a circuit panel. Alternatively, the unit can be packaged in a further package (not shown) of the type normally used to hold a conventional semiconductor chip. A “chip-scale” package as, for example, packages shown in certain embodiments of U.S. Pat. Nos. 5,679,977 and 5,518,964 can be employed. In certain embodiments taught in these patents, a package is formed by attaching a unitary package substrate to a wafer or other assemblage including a plurality of individual semiconductor chips, and then severing the packaged substrate along with the wafer. The same approach can be applied in packaging units of the types shown in FIG. 8 and the other units discussed herein. Thus, the package substrate can be applied after application of the cover plate and sealing of the various units, or can be carried by the cover plate when the cover plate is assembled to the wafer. This package substrate may be severed along with the cover plate and wafer. The larger package may provide features such as additional physical protection to the unit and package terminals, connected to terminals 344 of the unit, the packaged terminals being in a form more readily mountable to a circuit panel or other larger substrate during assembly of a larger circuit.

A unit 494 in accordance with yet another embodiment of the invention (FIG. 11) is similar to the unit discussed above with reference to FIG. 8. Here again, the microelectronic element 402 is mounted between a rear cover 422 and a front cover 430. Element 402 is fully encompassed inside the space imposed by the front cover 430, rear cover 422 and seals 442, but is isolated from the front and rear covers and from the seals. Here again, there is a front space 408 between element 402 and the front cover, and a rear space 406 between the element 402 and the rear cover or chip 422. In this embodiment, however, the microelectronic element is connected directly to connections 444 projecting through the front cover 430. For example, the front cover 430 may include traces 401 on the interior surface 441 of the front cover and contact elements 403 projecting rearwardly from these traces. Desirably, contact elements 403 are deformable to at least some degree so as to compensate for factors such as differences in the height or forward-to-rearward extent of seals 442 and the thickness of the microelectronic element itself. The chip 422 is provided with similar traces and projecting contact elements 409. Prior to assembly, the microelectronic elements 402 may be mounted to the projecting contact elements 403 on the front cover plate. When the wafer and front cover plate are united with the seals therebetween, the projecting contact elements 409 on the chips engage the microelectronic elements 402. For example, where the microelectronic element 402 includes electrodes 411 and 413 on its front and rear surfaces, the projecting contact elements may engage the electrodes and may be bonded thereto as, for example, by heating the element to activate bonding material carried on the electrodes or on the projecting contact elements.

Alternatively or additionally, connections from the microelectronic element 402 through the front cover 430 may be formed in any of the ways discussed herein for forming connections through the front cover from the chip. For example, connections 445 are formed by providing posts 417 on the forwardly-facing surface of microelectronic element 402 and aligning these posts with holes in the cover plate when the cover plate is assembled to the wafer. These posts are sealed to the cover plate in the same way as discussed above as, for example, by applying a solder or other bonding material, so that the solder fills any gaps between the posts and the front cover. The unit desirably further includes connections 419 extending through the front cover from contacts 434 on the chip 422. In a further variant (not shown), some of the connections 419 from the chip also make connection with traces 401 or other conductive elements on the front cover plate, which are electrically connected to the microelectronic elements.

It is not essential to provide an active semiconductor chip as the rear cover plate in structures as discussed with reference to FIGS. 10 and 11. For example, the rear cover may be a dielectric element or an element having only passive electrical connections and passive electrical devices thereon. In yet another variant, the microelectronic element 402 may be provided with connections extending through both the front and rear covers as, for example, by providing posts similar to posts 417 extending rearwardly from the rear surface of microelectronic element 402.

Elements other than quartz crystals can be mounted in units as discussed with reference to FIGS. 10 and 11. For example, an optically active element such as an emitter, detector or a combined emitter and detector, as discussed above with reference to FIG. 1, can be mounted in a unit as discussed with reference to FIGS. 10 and 11. In this instance, one or both of the cover plates desirably is transparent to radiation in the band employed by the optically active element.

A unit 501 according to yet another embodiment of the invention incorporates a rear element 503 and a front element 505, sealed to one another by seals 507 so as to form a closed space 508. The unit 501 further includes a chemically active device such as a catalyst or reagent 509 disposed within the chamber. In this embodiment, cover 505 has a hole 511 extending through it. The wall of hole 511, defined by cover 505, is substantially in the form of a cone or other surface of revolution about an axis 513 extending through the cover, such hole having a diameter which increases progressively in the rearward direction, toward space 508. A spherical valve element 515 is disposed in hole 511 so that the value element 515 can be moved between the closed position shown in solid lines in FIG. 10, and the open position 515″ illustrated in broken lines. A stop 517 is provided on the rear element 503 to limit rearward travel of valve element 515, and thus prevent dislodgement of the valve element from hole 511. Valve element 515 and hole 511 thus form a check value which allows fluid flow in the rearward direction, into the space 508 within the unit, but which substantially stops fluid flow in the opposite direction. A similar but oppositely-facing check valve is formed by a further valve element 521, disposed in a hole 523 through the front cover. Hole 523 has an opposite taper, so that the diameter of hole 523 increases progressively in the forward direction. Here again, the wall of hole 523 is formed substantially in the form of a surface of revolution about an axis 525. To form valves as shown in FIG. 10, cover 505 desirably is formed form a material having substantially isotropic properties, such as glass or metal. Unlike silicon, which tends to etch preferentially along planes determined by the crystal planes of the silicon, an isotropic etch material such as glass or metal can be readily etched or ablated to form a hole in the form of a surface of revolution such as a conical hole. The hole surface desirably is smooth. For example, where a glass cover plate is subjected to ablation or other processing involving heating of the glass to form the through hole, surface tension of the molten glass tends to form a smooth surface. In a further variant, the front cover may be formed from a metal or plastic by molding or casting. The tapered holes may be formed by the molding or casting operation. Units of this type can be used as microchemical processing devices. A manifold plate or other structure defining inlet and outlet passages 529 and 531, in communication with the valves, may be provided on the exterior surface of cover 505. This structure may include appropriate fittings for connection to other fluid-handling devices.

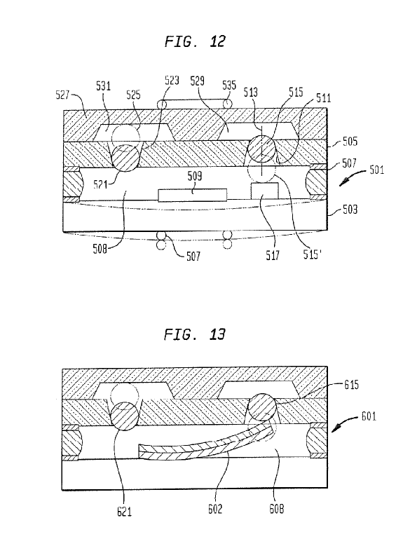

In a variant of this arrangement, holes and valves of this type may be provided in both covers, or in only the rear cover. Also, structures having such valves can incorporate microelectronic or micromechanical structures which interact with the fluid passed through the space 508. In a further variant, one or both of the covers may be flexible and may be repeatedly flexed to vary the internal volume of space 508, thereby pumping fluid through the space 508. In the arrangement depicted in FIG. 12, rear cover 503 is flexible. An electromagnetic coil 535 is formed on or mounted to front cover 505 or manifold plate 527, whereas a similar coil 507 is formed on or mounted to rear cover 503. By passing alternating currents through these coils, the coils may be caused to mutually attract and may mutually repel one another, so as flex rear cover 503. Alternatively or additionally, the device may be engaged in an external mechanical device which serves to squeeze and release the device repeatedly.

The unit 601 of FIG. 13 incorporates similar valves 615 and 621 in conjunction with an element which can be actuated to forcibly close valve 615. The closing element 602 is a bimetallic strip. When the strip is at one temperature, the strip is curved as depicted in FIG. 13. At a different temperature, strip 602 relaxes and allows opening of valve 615. Alternatively or additionally, a piezoelectric, magnetostrictive or other force-generating device may be used to forcibly close the valve. The bimetallic strip 602 discussed with reference to FIG. 13 can be actuated by directing energy into the space 602 enclosed by the front and rear covers as, for example, by directing radiant energy through one or both of the covers. Other devices which can be actuated without applying electrical signals directly to the devices include inductively-coupled and capacitively coupled electrical devices. Thus, units incorporating such devices need not have electrical connections exposed at the outside of the unit.

Numerous variations and combinations of the features discussed above can be employed. For example, any of the different seals and electrical connections discussed herein can be employed in any of the embodiments which use seals and electrical connections. Also, additional elements can be added to the structures shown herein.

The fabrication process discussed above with reference to FIG. 1 uses a complete unitary wafer incorporating an array of chips formed integrally with one another. In a variant, a part of such a wafer may be used. In other variants, similar processes can be performed using arrays of separate chips on a supporting substrate separate from the chips in place of a wafer. For example, the separate chips can be temporarily held on a support as, for example, by an adhesive susceptible to degradation. Likewise, temporary supports holding arrays of separate covers can be used in place of the unitary cover plates discussed. Preferably after joining and seal formation, the individual covers or wafers are detached from the supports. In a further variant, the support or supports can be left in place and severed in the manner discussed above, so that each unit formed in the severing process includes a part of each support.

As these and other variations and combinations of the features discussed herein can be utilized without departing from the present invention as defined by the claims, the foregoing description of the preferred embodiments should be taken byway of illustration rather than by way of limitation of the invention as defined by the claims.

What is claimed as new and desired to be protected by Letters Patent of the United States is:

1. A microelectronic package comprising:
(a) a microelectronic element having front and rear sides,
(b) a front cover overlying the front side of said element, said front cover being spaced from said front side so as to define a front space between said front side and front cover;
(c) a rear cover overlying the rear side of said element, said rear cover being spaced from said rear side so as to define a rear space between said rear side and said rear cover; and
(d) one or more seals surrounding at least a portion of said element connecting said covers to said element, to one another or both.

2. A package as claimed in claim 1 further comprising electrically conductive connections extending from a portion of said element surrounded by said seals through at least one of said covers.

3. A package as claimed in claim 1 wherein said element includes a central portion and a peripheral portion surrounding said central portion, said seals including a front seal extending between said peripheral portion of said element and said front cover.

4. A package as claimed in claim 3 wherein said seals include a rear seal extending between said peripheral portion of said element and said rear cover.

5. A package as claimed in claim 4 wherein said element and said covers have substantially equal dimensions in horizontal directions parallel to said front surface.

6. A package as claimed in claim 1 wherein said seals include a loop seal extending between said covers so that said loop seal and said covers cooperatively define a sealed chamber including said front and rear spaces, said element being disposed within said chamber.

7. A package as claimed in claim 6 wherein said element does not contact said loop seal.

8. A package as claimed in claim 6 further comprising spacers mechanically supporting said element out of contact with said front and rear covers.

9. A package as claimed in claim 6 further comprising internal electrical connections extending between said element and at least one of said covers.

10. A package as claimed in claim 9 wherein said at least one of said covers includes a circuit element, said internal electrical connections electrically connecting said element to said circuit element.

11. A package as claimed in claim 10 further comprising electrically conductive connections extending from one of said covers which includes said circuit element through the other one of said covers.

12. A package as claimed in claim 1 wherein said element includes a detector sensitive to radiation and at least one of said covers is transparent to said radiant energy.

13. A package as claimed in claim 12 wherein said element includes an emitter adapted to emit radiant energy.

14. A sensing unit comprising a package as claimed in claim 13 and a reflector fixed to said package but spaced from said package so as to define an analyte space between said package and said reflector, said reflector and said package being constructed and arranged so that light emitted by said emitter will pass through one of said covers, through said analyte space to said reflector, from said reflector through said analyte space and through one of said covers to said detector.

15. A sensing unit as claimed in claim 14 wherein said emitter is arranged to direct radiation forwardly through said front cover, said detector is arranged to detect radiation passing rearwardly through said front cover, and said reflector overlies said front cover so that said analyte space is disposed between said reflector and said front cover.

16. A sensor including:
(a) a microelectronic element having front and rear surfaces, said microelectronic element including an emitter adapted to emit radiation in a selected wavelength band forwardly from said front surface and a detector adapted to detect radiation in said band directed rearwardly to said front surface;
(b) a front cover overlying said front surface, said front cover having a window portion aligned with said emitter and detector, at least said window portion being substantially transparent to radiation in said band;
(c) a seal encircling said emitter and detector and extending rearwardly from said front cover; and
(d) one or more electrical connectors extending through said front cover, said electrical connectors being electrically connected to said microelectronic element.

17. A sensor as claimed in claim 16 wherein said microelectronic element includes a unitary substrate, said emitter and detector being disposed on said unitary substrate.

18. A sensor as claimed in claim 17 wherein said emitter and detector include semiconductor elements epitaxially grown on said substrate.

19. A sensor as claimed in claim 17 wherein said substrate consists essentially of silicon.

20. A sensor as claimed in claim 16 wherein said seal extends from said front cover to said microelectronic element.

21. A sensor as claimed in claim 20 wherein at least said window portion of said front cover is spaced from said microelectronic element so that said front cover and said element define a front space therebetween.

22. A sensor as claimed in claim 21 further comprising a thermal insulator overlying said rear surface of said element.

23. A sensor as claimed in claim 22 wherein said thermal insulator includes a rear cover overlying said rear surface of said element, at least a portion of said rear cover being spaced apart from said element so that said rear cover and said element define a rear space between said rear cover and said element.

24. A sensor as claimed in claim 16 wherein at least some of said electrical connectors extend from said element through said front cover.

25. A sensor as claimed in claim 16 further comprising a reflector overlying said front cover and spaced from said front cover so that said reflector and said front cover define an analyte space therebetween, said reflector being operative to reflect energy emitted by said emitter through said front cover and said analyte space back through said analyte space to said detector.

26. A sensor as claimed in claim 25 wherein said reflector includes electrically conductive elements connected to said electrical connectors.

27. A sensor as claimed in claim 26 wherein said reflector has a proximal surface facing toward said front cover and a distal surface facing away from said front cover, said electrically conductive elements including terminals exposed at said distal surface.

28. A sensor as claimed in claim 26 wherein said reflector is a circuit panel extending outwardly beyond said unit and said front cover in one or more horizontal directions, said circuit panel including electrically conductive traces connected to said electrical connectors.

29. A sensor comprising:
(a) a reflector having a proximal surface and electrically conductive features, at least a portion of said proximal surface being adapted to reflect radiation in a predetermined wavelength band;
(b) a microelectronic element including an emitter and a detector mounted to said reflector so that there is an analyte space between said microelectronic element and said proximal surface of said reflector, said emitter being arranged to direct radiation in said band through said analyte space to said reflector so that said radiation will be reflected by said reflector back through said analyte space to said detector, said microelectronic element being electrically connected to said electrically conductive features of said reflector.

30. A sensor as claimed in claim 29 wherein said reflector has a distal surface facing away from said microelectronic element and said electrically conductive features include terminals exposed at said distal surface.

31. A sensor as claimed in claim 30 wherein said reflector has horizontal dimensions substantially equal to or less than the horizontal dimensions of said microelectronic element.

32. A sensor as claimed in claim 29 wherein said reflector is a circuit panel extending outwardly beyond said microelectronic element in at least one horizontal direction, and wherein said electrically conductive features include traces on said circuit panel.

33. A method of making a microelectronic package comprising the steps of:
(a) assembling a front cover plate to a front side of a main wafer so that said front cover plate is spaced from said front side of said main wafer;
(b) providing front spacing elements extending between said front cover plate and said main wafer;
(c) assembling a rear cover plate to a rear side of said main wafer so that rear cover plate is spaced from said rear side of said main wafer;
(d) providing rear spacing elements extending between said rear side of said main wafer and said rear cover plate; and
(e) after said assembling and providing steps, severing said plates and wafer to form a plurality of units, each including a region of said main wafer, regions of said front and rear plates, and front and rear spacing elements connecting said regions of said plates to said region of said main wafer.

34. A method as claimed in claim 33 wherein said step of providing front spacing elements includes providing front seals, each such seal enclosing a region of said front side.

35. A method as claimed in claim 34 wherein said step of providing rear spacing elements includes providing rear seals in alignment with said front seals, each said rear seal enclosing a region of said rear surface.

36. A method as claimed in claim 35 wherein said severing step includes severing said wafer and said plates along said front and rear seals.

37. A method as claimed in claim 34 further comprising forming (i) electrical connections extending from the regions of said front surface enclosed by said front seals through said front plate prior to said severing step; and (ii) sealing said front plate at locations where said electrical connections pass through said front plate.

38. A method of as claimed in claim 34 further comprising providing a reflector plate overlying a surface of said front plate and reflector spacing elements extending between said reflector plate and said front plate prior to said severing step, said reflector spacing elements being spaced apart from one another so as to define gaps therebetween, said severing step including severing said reflector plate so that each said unit includes a portion of said reflector plate.

39. A method of making a plurality of sensors including:
(a) providing a wafer-level assembly including a main wafer having a plurality of regions, each of said regions including an emitter operative to emit light and a detector operative to detect light and a front plate at least partially transparent to said light;
(b) attaching a reflector plate to said front plate so that said reflector plate is spaced apart from said front plate and reflector spacing elements extend between said front plate and said reflector plate at spaced-apart locations; and
(c) after said providing and attaching steps, severing said assembly and said reflector plate to provide a plurality of individual units, each including a region of said main wafer, a portion of said front plate forming a front cover, a portion of said reflector plate forming a reflector, an analyte space between the reflector front cover, and a plurality of said reflector spacing elements, such analyte space being open to the exterior of the unit through spaces between the reflector spacing elements.

40. A method as claimed in claim 39 wherein at least some of said reflector spacing elements are electrically conductive, the method further including the step of electrically connecting the conductive reflector spacing elements to regions of said main wafer.

41. A sensor including:
(a) a semiconductor chip including an emitter adapted to emit radiant energy in a wavelength band in a forward direction and a detector adapted to detect radiant energy in said wavelength band; and
(b) a reflector fixed to said chip forward of said emitter and detector so that radiant energy emitted by said emitter will be reflected to said detector, and
(c) a structure defining an analyte space open for passage of an analyte therethrough, said analyte space being disposed between said chip and said reflector, whereby radiant energy passing to and from said reflector will pass through analyte in said space.

42. A sensor including:
(a) a semiconductor chip including an emitter adapted to emit radiant energy in a wavelength band in a forward direction and a detector adapted to detect radiant energy in said wavelength band; and
(b) a reflector fixed to said chip forward of said emitter and detector so that radiant energy emitted by said emitter will be reflected to said detector, said reflector being exposed to an environmental condition in the vicinity of said sensor and having reflectivity which varies in response to said environmental condition.
